(19) United States
(12) Patent Application Publication
(10) Pub. No.: US 2008/0048230 A1
(43) Pub. Date: Feb. 28, 2008

(54) Semiconductor device and method for manufacturing the same

(75) Inventor: Yasushi YAMAZAKI, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: Elpida Memory, Inc., Tokyo (JP)

(21) Appl. No.: 11/894,840

(22) Filed: Aug. 22, 2007

(30) Foreign Application Priority Data
Aug. 22, 2006 (JP) 2006-225251

(51) Int. Cl. H01L 27/108; H01L 21/336

(52) U.S. Cl. 257/300; 438/270

(57) ABSTRACT

A semiconductor device including a semiconductor substrate and a recessed transistor provided on the semiconductor substrate, wherein the recessed transistor includes a recess formed in a surface of the semiconductor substrate, an insulating film provided on a surface in the recess, a gate electrode at least partly buried in the recess, and a first diffusion layer and a second diffusion layer formed in a surface of the semiconductor substrate with the gate electrode located between the first diffusion layer and the second diffusion layer, and wherein the insulating film includes a thicker film portion between the first diffusion layer and the gate electrode, the thicker film portion being thicker than a portion of the insulating film located between the gate electrode and a channel region of the recessed transistor.

### BACKGROUND OF THE INVENTION

1. Field of the Invention

The present invention relates to a semiconductor device and a method for manufacturing the semiconductor device, and more specifically, to a semiconductor device having a recessed transistor having a recessed gate structure, and a method for manufacturing the semiconductor device.

2. Description of the Related Art

A transistor having a recessed gate structure (hereinafter referred to as recess channel transistors) has been proposed in order to inhibit a short channel effect on access transistors in a cell array (hereinafter referred to as cell transistors), which results from increasingly miniaturized DRAM cells (J. Y. KIM et al., Symp. on VLST Tech., p 11-12, 2003).

Further, with respect to the structure of recess channel transistors, a recess channel transistor has been proposed which has an asymmetric diffusion structure with an asymmetric source and drain diffusion layer. The asymmetric diffusion structure makes it possible to extend refresh time, which has an effect on the power consumption of a DRAM.

US Patent Application Publication No. 2006-0049445A1 discloses an example of a recess channel transistor having an asymmetric diffusion structure.

FIG. 4 shows an example of the structure of a recess channel transistor having an asymmetric diffusion layer structure. An isolation region 12 partitioning an element formation region (active region) 30 is formed on a major surface of a P-type silicon substrate (Si substrate) 11. In the element formation region 30, a recess (Si recess portion) 13 is formed in a surface of the Si substrate 11, and a gate insulating film 20 is formed on a surface of an inner wall of the recess 13. A gate electrode 16 buried in the recess portion 13 is formed on the gate insulating film 20. A source region and a drain region of a transistor are located across the gate electrode 16. In the element formation region 30, a P-type punch through stopper layer 17 is formed on the bit line side. A shallow N-type diffusion layer 18 making up one of the source and drain regions is formed on the P-type punch through stopper layer 17. A deep N-type diffusion layer 19 making up the other of the source and drain regions is formed on the storage node side.

With reference to FIGS. 5A to 5F, description will be given of an example of a method for manufacturing the recessed transistor shown in FIG. 4. First, the isolation region 12 of depth about 300 nm is formed on the P-type Si substrate 11 using an STI (Shallow Trench Isolation) technique. Then, a pad oxide film 21 of thickness about 20 nm is formed on the element formation region 30 using a thermal oxidation process (FIG. 5A). A dry etching technique with a photo resist 22 as a mask is used to form the Si recess portion 13 of width about 90 nm and depth about 150 nm at a position at which a gate electrode is to be formed (FIG. 5B). In this state, the photo resist 22 is removed, and the pad oxide film 21 present on the substrate surface portion is etched away with a solution containing hydrofluoric acid (HF). An Si oxide film forming the gate insulating film 20 is formed on the Si substrate 11 to a thickness of about 6 nm by means of thermal oxidation process (FIG. 5C).

Then, an impurity-doped silicon (DOPOS) film 23 of phosphorous concentration 2E20 cm⁻³ is formed to a thickness of about 100 nm as a gate electrode film. A tungsten silicide (WSi₂) film 24 is formed to a thickness of about 70 nm by a normal CVD process. Moreover, a silicon nitride (SiN) film 25 is formed using the CVD process, and a photo resist 22 is formed using a photolithography process so as to mask a position corresponding to the Si recess portion 13 (FIG. 5D). The SiN film 25, the WSi₂ film 24, and the DOPOS film 23 are sequentially etched using a dry etching process to form the gate electrode 16.

A photolithography process is subsequently used to form the photo resist 22 having an opening only on the bit line side of the element formation region. In this state, boron of dose 1E12 cm⁻² to 1E13 cm⁻² is injected with energy of 15 to 50 KeV. Arsenic of dose 1E13 cm⁻² to 1E14 cm⁻² is injected with energy of 20 to 50 KeV. The P-type punch through stopper layer 17 and the shallow N-type diffusion layer 18 are thus formed (FIG. 5E).

The photolithography process is similarly used to form a photo resist 22 having an opening only on the storage node side of the element formation region. Phosphorous of dose 5E11 cm⁻² to 1E14 cm⁻² is injected with energy of 10 to 50 KeV to form the deep N-type diffusion layer 19 (FIG. 5F). This results in a recess channel transistor structure.

In the above recess channel transistor having the asymmetric diffusion structure, an overlap capacity is formed between the gate electrode 16 and the deep N-type diffusion layer 19 and affects the high speed operation of a circuit. Accordingly, a reduction in overlap capacity improves the performance of the device. That is, an increase in the thickness of the gate oxide film in this region improves the high speed performance of the device. However, in a channel region, a decrease in the thickness of the gate insulating film increases the mutual conductance (Gm) of the transistor, resulting in an excellent switching property.

In the above recess channel transistor structure, when the equivalent oxide thickness of the gate insulating film in the channel region which is required to obtain appropriate transistor properties is defined as tox1, the corresponding overlap capacity C1 is unambiguously defined as C1=∈S/tox1 (S denotes an opposing area and ∈ denotes a dielectric constant) using the equivalent oxide thickness tox1. Here, reducing the overlap capacitance between the gate electrode and the deep N-type diffusion layer below C1 increases tox1, resulting in the high speed performance of the device. However, this reduces Gm of the transistor, preventing an appropriate switching property from being obtained. In short, with the transistor structure shown in FIG. 4, the high speed performance of the device is in what is called a tradeoff relationship with the switching property of the transistor. It is difficult to achieve a good balance between the high speed performance and the switching property.

### SUMMARY OF THE INVENTION

An object of the present invention is to provide a semiconductor device that makes it possible to achieve a good balance between the appropriate switching property of a recessed transistor and the high speed performance of the device.

According to a first aspect of the present invention, there is provided a semiconductor device comprising a semiconductor substrate and a recessed transistor provided on the semiconductor substrate,

wherein the recessed transistor comprises:

a recess formed in a surface of the semiconductor substrate,

an insulating film provided on a surface in the recess,

a gate electrode at least partly buried in the recess, and

a first diffusion layer and a second diffusion layer formed in a surface of the semiconductor substrate with the gate electrode located between the first diffusion layer and the second diffusion layer, and

wherein the insulating film comprises a thicker film portion between the first diffusion layer and the gate electrode, the thicker film portion being thicker than a portion of the insulating film located between the gate electrode and a channel region of the recessed transistor.

According to a second aspect of the present invention, there is provided a method for manufacturing a semiconductor device comprising the steps of:

forming a first diffusion layer in a surface of a semiconductor substrate so as to form a first region in which the first diffusion layer is formed and a second region in which the first diffusion layer is not formed,

forming a recess in a surface of the semiconductor substrate adjacent to the first diffusion layer to form an exposed surface of the first diffusion layer and an exposed surface of the second region in the recess,

forming an oxide film on a surface in the recess using a thermal oxidation process so that the oxide film comprises a thicker film portion on the exposed surface of the first diffusion layer, the thicker film portion being thicker than a thinner film portion formed on the exposed surface of the second region,

forming a gate electrode on the oxide film in the recess, the gate electrode being at least partly buried in the recess, and

forming a second diffusion layer opposite to the first diffusion layer via the recess.

According to the present invention, the insulating film contacting the first diffusion layer is formed thick. Consequently, the device can be operated at a high speed by appropriately selecting the voltage polarity of a node connected to the first diffusion layer of the transistor. Further, the insulating film contacting the channel region is formed thin, resulting in the appropriate switching property of the transistor. This makes it possible to achieve a good balance between the high speed operation and the appropriate switching property.

The present invention also allows the thick insulating layer contacting the first diffusion layer and the thin insulating film contacting the channel region to be formed on the surface in the recess at a time by the thermal oxidation process. This enables the semiconductor device in accordance with the present invention to be manufactured by a simple process.

According to another aspect of the present invention, there is provided the semiconductor device as described above, wherein the semiconductor device comprises a memory cell comprising the recessed transistor as a cell transistor, a storage node to which the first diffusion layer is connected, and a data line to which the second diffusion layer is connected.

According to another aspect of the present invention, the insulating film may comprise a thinner film portion thinner than the thicker film portion, the thinner film portion being formed between the second diffusion layer and the gate electrode.

According to another aspect of the present invention, the gate electrode may comprise a polysilicon layer formed on the insulating film and at least partly buried in the recess and a metal containing film formed on the polysilicon layer.

According to another aspect of the present invention, the first diffusion layer may be formed deeper than the second diffusion layer. In this case, connecting the first diffusion layer to a storage node such as in a memory cell enables the refresh time to be extended.

According to another aspect of the present invention, a third diffusion layer in which impurities of a conductivity type different from that of the second diffusion layer are diffused may be formed under the second diffusion layer. This enables possible punch through to be inhibited.

According to another aspect of the present invention, the thicker film portion and the thinner film portion are preferably formed during the same thermal oxidation process. This simplifies the entire manufacturing process.

### BRIEF DESCRIPTION OF THE DRAWINGS

FIG. 1 is a sectional view showing an example of a DRAM making up a semiconductor device in accordance with an embodiment of the present invention;

FIG. 2 is a plan view of the DRAM shown in FIG. 1;

FIG. 3A is a sectional view showing a step of a process of manufacturing the DRAM shown in FIG. 1;

FIG. 3B is a sectional view showing a step succeeding the step shown in FIG. 3A;

FIG. 3C is a sectional view showing a step succeeding the step shown in FIG. 3B;

FIG. 3D is a sectional view showing a step succeeding the step shown in FIG. 3C;

FIG. 3E is a sectional view showing a step succeeding the step shown in FIG. 3D;

FIG. 3F is a sectional view showing a step succeeding the step shown in FIG. 3E;

FIG. 4 is a sectional view of a semiconductor device related to the present invention;

FIG. 5A is a sectional view showing a step of a process of manufacturing the DRAM shown in FIG. 4;

FIG. 5B is a sectional view showing a step succeeding the step shown in FIG. 5A;

FIG. 5C is a sectional view showing a step succeeding the step shown in FIG. 5B;

FIG. 5D is a sectional view showing a step succeeding the step shown in FIG. 5C;

FIG. 5E is a sectional view showing a step succeeding the step shown in FIG. 5D; and

FIG. 5F is a sectional view showing a step succeeding the step shown in FIG. 5E.

### DETAILED DESCRIPTION OF THE PREFERRED EMBODIMENTS

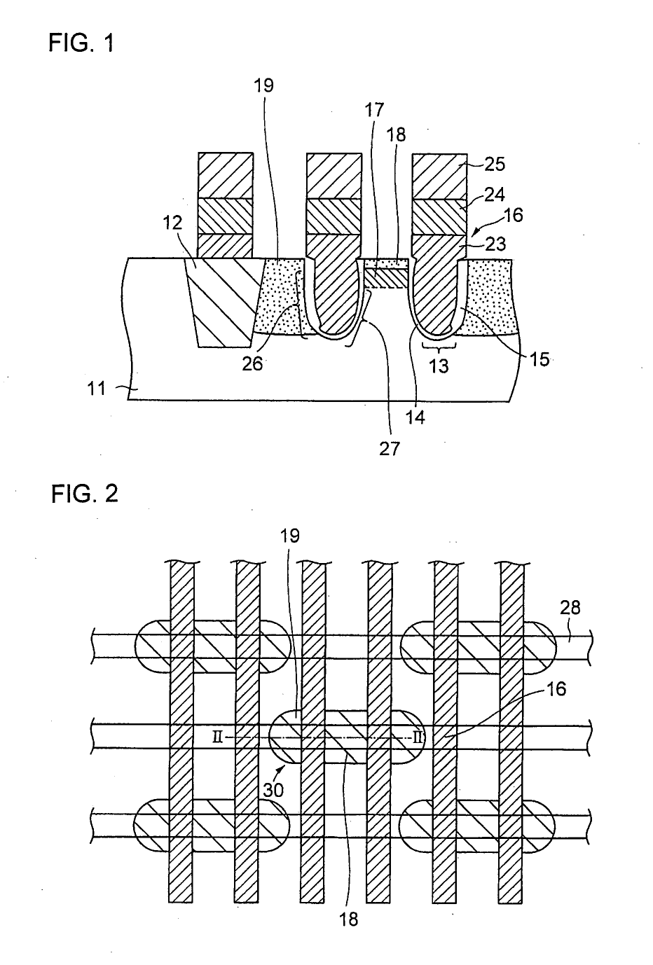

FIG. 1 is a sectional view showing an example of a DRAM making up a semiconductor device in accordance with an exemplary embodiment of the present invention. FIG. 2 is a plan view of the DRAM shown in FIG. 1. FIG. 1 shows a cross section taken along line II-II in FIG. 2. In FIG. 1, an isolation region 12 partitioning an element formation region is formed on a major surface of a P-type silicon substrate 11. In the element formation region, an Si recess portion 13 is formed, and a gate insulating film having a thicker film portion 15 and a thinner film portion 14 is formed on a surface of an inner wall of the Si recess portion 13. A gate electrode 16 buried in the Si recess portion 13 is formed on the gate insulating film. Diffusion layers 18 and 19 making up a source region and a drain region of a transistor are located across the gate electrode 16. In the element formation region 30, a P-type punch through stopper layer 17 is formed on the side closer to a bit line making up a cell node. A shallow N-type diffusion layer 18 making up one of the source and drain regions is formed on the P-type punch through stopper layer 17. A deep N-type diffusion layer 19 making up the other of the source and drain regions is formed on the side closer to a storage node. The gate electrode is composed of a DOPOS film 23 and a WSi₂ film 24. An SiN film 25 is formed on the WSi₂ film 24.

The gate insulating film has the thicker film portion 15 adjacent to the deep N-type diffusion layer 19 and the thinner film portion 14 adjacent to the shallow N-type diffusion layer 18, the P-type punch through stopper layer 17 and a channel region 27. For the dimensions of the portions, for example, the depth of the recess is about 150 nm, and a gate length (word line width) is at most 100 nm. The thicker film portion 15 of the gate insulating film has a thickness of about 15 nm, and the thinner film portion 14 has a thickness of about 7 nm. The thicker film portion preferably has a thickness at least 1.5 times, more preferably at least twice, as large as that of the thinner film portion. Moreover, the thickness of the thicker film portion is preferably set to be at least 10 nm. The upper limit of the thickness of the thicker film portion is not particularly limited but may be appropriately set provided that the desired element properties are obtained and that a decrease in productivity resulting from the difficulty of film formation for manufacture can be avoided.

In FIG. 2, each gate electrode 16 is configured as a word line extending in the row direction of a memory cell array in a DRAM device. The shallow diffusion layer 18 and the deep diffusion layer 19 are formed in each element formation region 30. Each bit line forming a data line extends over the corresponding element formation region 30 so as to overlap the region. The bit line is connected to the shallow diffusion layer 18 in the corresponding column. A stacked capacitive element is formed over each element formation region 30. A lower electrode of the stack capacitive element is connected to the corresponding deep diffusion layer 19. Plugs connecting the above components form a storage node.

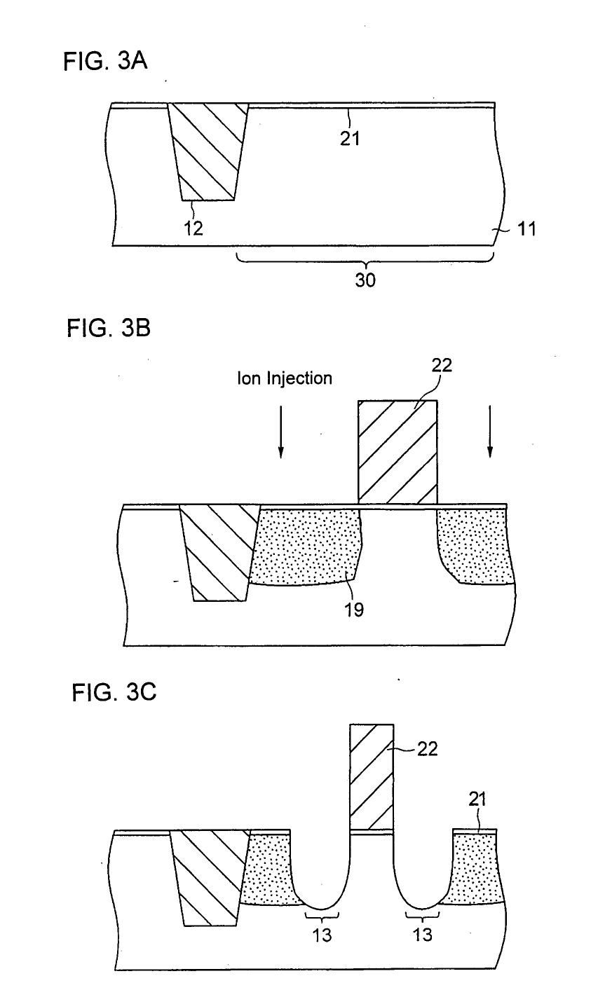

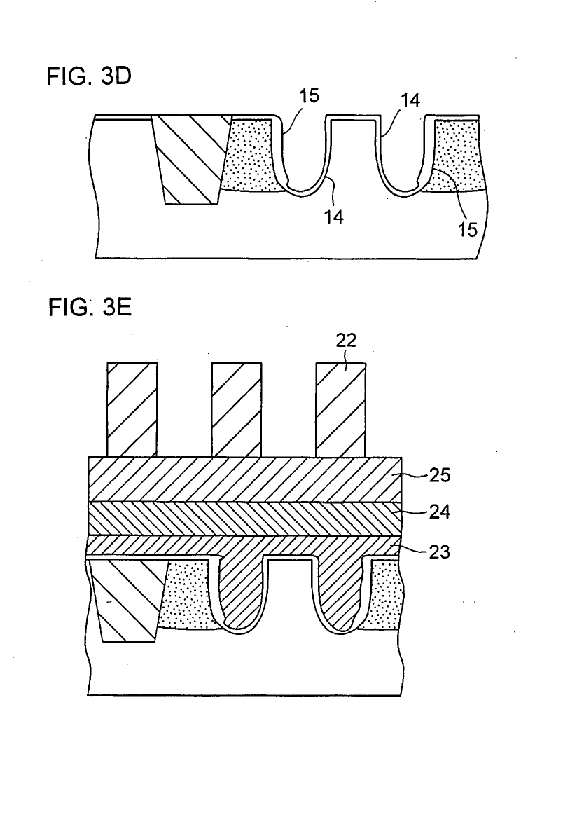

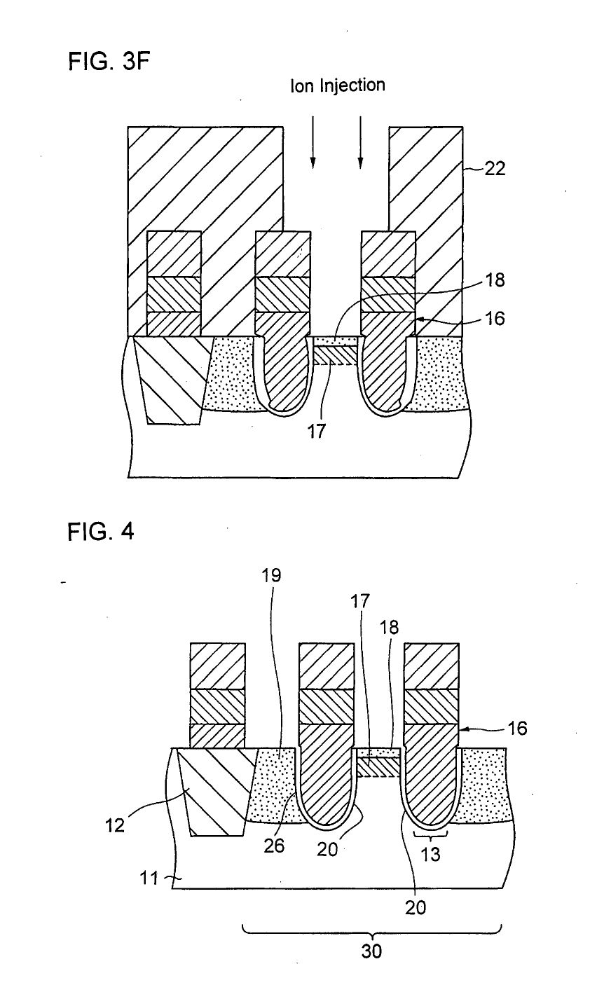

With reference to FIGS. 3A to 3F, description will be given of an example of a method for manufacturing the DRAM shown in FIGS. 1 and 2. The isolation region 12 of depth about 250 nm is formed on the P-type Si substrate using an STI (Shallow Trench Isolation) process. A pad oxide film 21 of thickness about 10 nm is formed by a thermal oxidation process (FIG. 3A). Then, a photolithography technique is used to pattern a photo resist film so that the photo resist film covers a portion of the element formation region connected to the bit line during the subsequent step. The photo resist film is then used as a mask to inject arsenic (As) of dose 1E13 cm⁻² to 1E15 cm⁻² with energy of 60 to 200 KeV. Phosphorous (P) of dose 1E13 cm⁻² to 1E15 cm⁻² is further injected with energy of 30 to 100 KeV. The deep N-type diffusion layer 19 is thus formed (FIG. 3B).

Then, the Si recess portion 13 is formed in the Si substrate 11 using the photolithography technique and a dry etching technique (FIG. 3C). At this time, the recess is formed in a portion including the boundary of the deep N-type diffusion layer 19 in the depth direction. This exposes the N-type diffusion layer 19 from a side wall of the Si recess portion 13 on the storage node side and exposes the substrate 11 from a side wall of the Si recess portion 13 on the bit line side.

The photo resist is removed, and a thermal oxide film is formed on a flat surface of the Si substrate to a film thickness of 7 nm by the thermal oxidation process (FIG. 3D). At this time, inside the recess the thickness of the oxide film contacting the diffusion layer on the bit line side is almost the same as that of the flat surface, 7 nm. The thinner film portion 14 is thus formed. The storage node-side oxide film contacting the diffusion layer with arsenic (As) and phosphorous (P) injected thereinto is subjected to faster oxidation under the effect t of impurities. The thickness of the oxide film thus becomes about 15 nm, forming the thicker film portion 15.

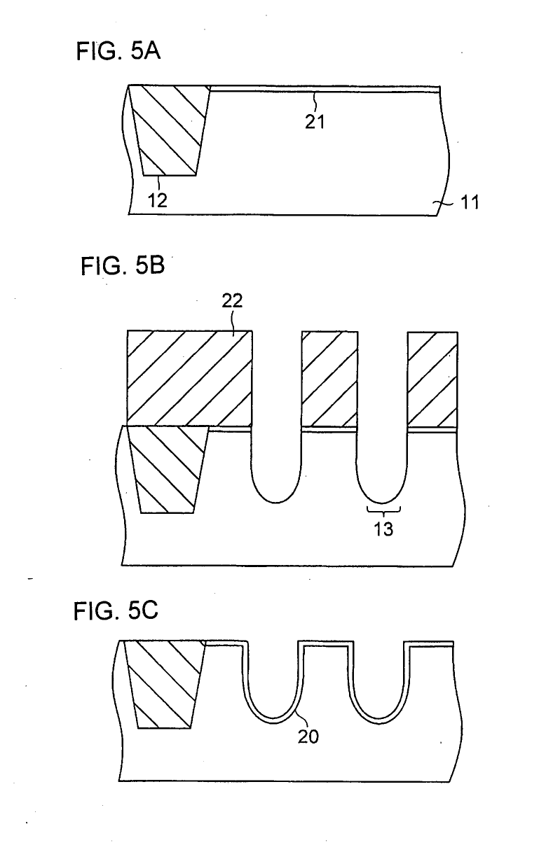

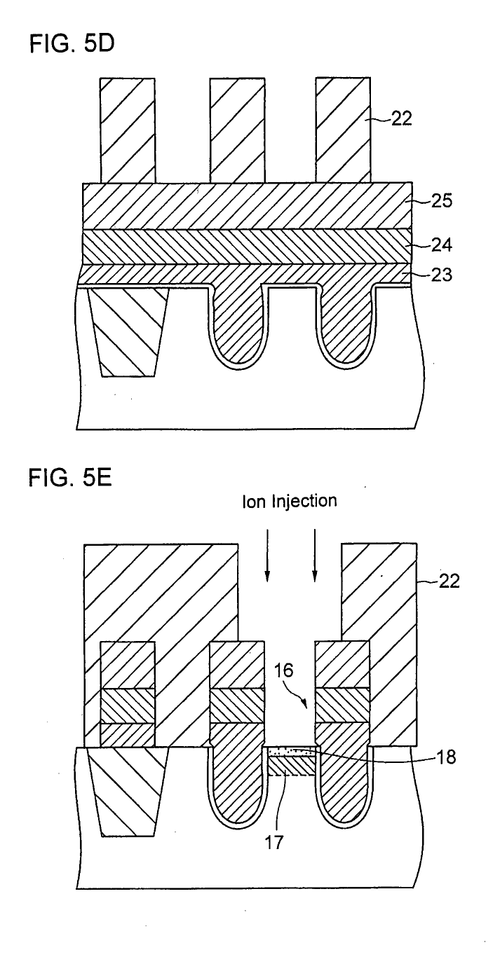

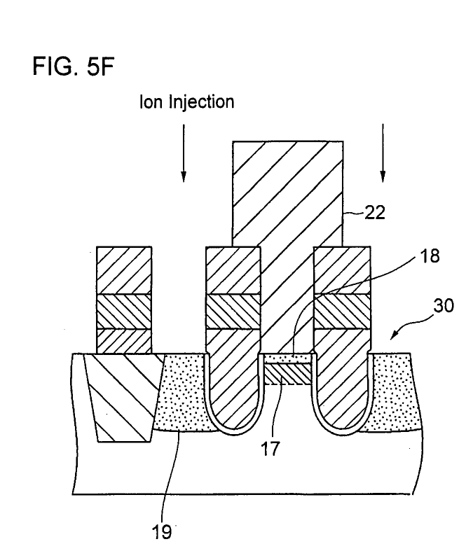

Then, a DOPOS film 23, a WSi₂ film 24, and an SiN film 25 are formed. A photo resist 22 is formed using the photolithography technique (FIG. 3E). The SiN film 25, the WSi₂ film 24, and the DOPOS film 23 are patterned with the photo resist 22 as a mask using the dry etching technique, to form a gate electrode. The photolithography technique is continuously used to form the photo resist 22 that opens only in a bit contact region. Boron (B) and phosphorous (P) are injected under conditions similar to those for the step described with reference to FIG. 5E to form the P-type punch through stopper layer 17 and the shallow N-type diffusion layer 18 (FIG. 3F). The photo resist 22 is removed to obtain the structure shown in FIG. 1.

Subsequently, an interlayer insulating film, a bit contact, and a capacitive contact are formed using the conventional method. Further, a capacitive element is formed on the capacitive contact and a bit line is formed on the capacitive element via the interlayer insulating film.

The above process uses the same number of photo masks as that used in the conventional process, preventing an increase in the number of masks used compared to that in the related art.

With the structure in accordance with the above embodiment, the increased thickness of a portion of the gate insulating film closer to the storage node enables a reduction in overlap capacity. Further, keeping the film thickness of the gate oxide film in the channel portion at the desired value enables a good balance to be achieved between the high speed performance of the device and the switching property of the transistor. Furthermore, forming the storage node-side diffusion layer deeper enables the refresh time to be extended.

What is claimed is:

1. A semiconductor device comprising a semiconductor substrate and a recessed transistor provided on the semiconductor substrate,
wherein the recessed transistor comprises:
a recess formed in a surface of the semiconductor substrate;
an insulating film provided on a surface in the recess;
a gate electrode at least partly buried in the recess; and
a first diffusion layer and a second diffusion layer formed in a surface of the semiconductor substrate with the gate electrode located between the first diffusion layer and the second diffusion layer, and
wherein the insulating film comprises a thicker film portion between the first diffusion layer and the gate electrode, the thicker film portion being thicker than a portion of the insulating film located between the gate electrode and a channel region of the recessed transistor.

2. The semiconductor device according to claim 1, wherein the semiconductor device comprises a memory cell comprising the recessed transistor as a cell transistor; a storage node to which the first diffusion layer is connected; and a data line to which the second diffusion layer is connected.

3. The semiconductor device according to claim 1, wherein the insulating film comprises a thinner film portion thinner than the thicker film portion, the thinner film portion being formed between the second diffusion layer and the gate electrode.

4. The semiconductor device according to claim 1, wherein the gate electrode comprises a polysilicon layer formed on the insulating film and at least partly buried in the recess and a metal containing film formed on the polysilicon layer.

5. The semiconductor device according to claim 1, wherein the first diffusion layer is formed deeper than the second diffusion layer.

6. The semiconductor device according to claim 1, further comprising a third diffusion layer formed under the second diffusion layer, wherein impurities of a conductivity type different from that of the second diffusion layer are diffused in the third diffusion layer.

7. A method for manufacturing a semiconductor device comprising the steps of:
forming a first diffusion layer in a surface of a semiconductor substrate so as to form a first region in which the first diffusion layer is formed and a second region in which the first diffusion layer is not formed;
forming a recess in a surface of the semiconductor substrate adjacent to the first diffusion layer to form an exposed surface of the first diffusion layer and an exposed surface of the second region in the recess;
forming an oxide film on a surface in the recess using a thermal oxidation process so that the oxide film comprises a thicker film portion on the exposed surface of the first diffusion layer, the thicker film portion being thicker than a thinner film portion formed on the exposed surface of the second region;
forming a gate electrode on the oxide film in the recess, the gate electrode being at least partly buried in the recess; and
forming a second diffusion layer opposite to the first diffusion layer via the recess.

8. The method for manufacturing the semiconductor device according to claim 7, wherein the thicker film portion and the thinner film portion are formed during the same thermal oxidation process.

9. The method for manufacturing the semiconductor device according to claim 7, wherein the second diffusion layer is formed shallower than the first diffusion layer.

10. The method for manufacturing the semiconductor device according to claim 7, further comprising the step of introducing impurities of a conductivity type different from that of the second diffusion layer, under the second diffusion layer to form a third diffusion layer.
